(19) United States
(12) Patent Application Publication
(10) Pub. No.: US 2026/0053057 A1
(43) Pub. Date: Feb. 19, 2026

(54) ENCAPSULATION DELAMINATION PREVENTION STRUCTURES AT DIE EDGE

(71) Applicant: Wolfspeed, Inc., Durham, NC (US)

(72) Inventors: Daniel Richter, Raleigh, NC (US); Devarajan Balaraman, Apex, NC (US); Brice McPherson, Fayetteville, AR (US)

(21) Appl. No.: 18/806,895

(22) Filed: Aug. 16, 2024

(51) Int. Cl. H01L 23/16; H01L 21/56; H01L 23/31; H01L 29/16; H01L 29/78; H01L 29/872

(52) U.S. Cl. CPC H01L 23/16; H01L 21/56; H01L 23/3171; H10D 8/60; H10D 30/665; H10D 62/8325

(57) ABSTRACT

A power semiconductor device includes a semiconductor structure comprising an active region, an encapsulation material on the semiconductor structure, and a plurality of adhesion features in or on the semiconductor structure along an interface with the encapsulation material. The interface is laterally between the active region and at least one edge of the semiconductor structure. Related devices and fabrication methods are also discussed.

### FIELD

The present disclosure is directed to power semiconductor devices, and more particularly, to reliability of power semiconductor devices.

### BACKGROUND

Power semiconductor devices are used to carry large currents and support high voltages. A wide variety of power semiconductor devices are known in the art including, for example, power Metal Insulator Semiconductor Field Effect Transistors (“MISFETs,” including Metal Oxide Semiconductor FETs (“MOSFETs”)), bipolar junction transistors (“BJTs”), Insulated Gate Bipolar Transistors (“IGBTs”), Schottky diodes, Junction Barrier Schottky (“JBS”) diodes, merged p-n Schottky (“MPS”) diodes, Gate Turn-Off Thyristors (“GTOs”), MOS-controlled thyristors and various other devices. These power semiconductor devices are generally fabricated from wide bandgap semiconductor materials such as silicon carbide (SiC) or gallium nitride (GaN) based materials (herein, the term “wide bandgap semiconductor” encompasses any semiconductor having a bandgap of at least 1.4 eV). Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential.

A conventional silicon carbide power device typically has a silicon carbide substrate, such as a silicon carbide wafer, on which an epitaxial layer structure is formed. This epitaxial layer structure (which may include one or more separate layers) functions as a drift layer or drift region of the power semiconductor device. The device typically includes an “active region,” which includes one or more “unit cell” structures that have a p-n junction and/or a Schottky junction. The active region may be formed on and/or in the drift region. The active region acts as a main junction for blocking voltage in the reverse bias direction and providing current flow in the forward bias direction.

Power semiconductor devices may have a unit cell configuration in which the active region of each power semiconductor device includes a large number of individual unit cell structures that are electrically connected in parallel to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated.

Power semiconductor devices can have a lateral structure or a vertical structure. In a device having a lateral structure, the terminals of the device (e.g., the drain, gate and source terminals for a power MOSFET) are on the same major surface (i.e., upper or lower) of a semiconductor structure. In contrast, in a device having a vertical structure, at least one terminal is provided on each major surface of the semiconductor structure (e.g., in a vertical MOSFET, the source and gate may be on the upper surface of the semiconductor structure and the drain may be on the bottom surface of the semiconductor structure). For example, power Schottky diodes typically have a vertical structure where the anode contact is formed on a first major surface (e.g., the top surface) of a semiconductor structure, and the cathode contact is formed on the other major surface (e.g., the bottom surface). Vertical structures are typically used in very high power applications, as the vertical structure allows for a thick semiconductor drift layer that can support high current densities and block high voltages. The semiconductor structure may or may not include an underlying substrate. Herein, the term “semiconductor structure” refers to a structure that includes one or more layers such as semiconductor substrates and/or semiconductor epitaxial layers.

A relatively thick protective overcoating layer, is often used in power semiconductor device chips for electrical and/or chemical protection (e.g., arcing, moisture, etc.) of the semiconductor layer structure. The protective overcoating may be a polymer (e.g., polyimide) or other non-conductive layer (e.g., silicon nitride), which may differ in materials and/or characteristics as compared to the materials of the semiconductor structure, and may be formed on the active region of the semiconductor structure. Thermomechanical stress, which may originate from differences or mismatch in the coefficients of thermal expansion (CTE) of the semiconductor structure and overlying layers, can be significant in larger power semiconductor device chips, potentially leading to cracking and/or delamination of the overlying layers.

### SUMMARY

According to some embodiments, a power semiconductor device includes a semiconductor structure having an active region, an encapsulation material on the semiconductor structure, and a plurality of adhesion features in or on the semiconductor structure along an interface with the encapsulation material, where the interface is laterally between the active region and at least one edge of the semiconductor structure.

In some embodiments, the adhesion features protrude from and/or are recessed in the semiconductor structure with a repeating pattern along the interface.

In some embodiments, the adhesion features are recessed in and may include portions of the semiconductor structure.

In some embodiments, the adhesion features protrude from and may include a material different than a semiconductor material of the semiconductor structure.

In some embodiments, a first adhesion strength between the adhesion features and the encapsulation material is greater than a second adhesion strength between the semiconductor structure and the encapsulation material.

In some embodiments, a third adhesion strength between the adhesion features and the semiconductor structure is greater than the second adhesion strength.

In some embodiments, the interface may include an upper surface of the semiconductor structure that extends between the active region and the at least one edge, and a side surface of the semiconductor structure that extends from the at least one edge toward a bottom surface of the semiconductor structure.

In some embodiments, the adhesion features define geometric shapes (e.g., rectangular, triangular, semi-elliptical, or trapezoidal shapes) in cross-section.

In some embodiments, the adhesion features continuously extend along the interface in plan view.

In some embodiments, the adhesion features are distributed along the interface in plan view.

In some embodiments, an area density of the adhesion features at a corner portion of the semiconductor structure is greater than that of at least one other portion of the semiconductor structure along the interface.

In some embodiments, the at least one other portion of the semiconductor structure is free of the adhesion features along the interface.

In some embodiments, a protective overcoating may be provided on the semiconductor structure laterally adjacent the encapsulation material and exposing the interface, where the protective overcoating may include a non-conductive material different from that of the encapsulation material.

In some embodiments, the interface is a first interface, and where the plurality of adhesion features are further provided in or on the semiconductor structure along a second interface with the protective overcoating, where the second interface is laterally adjacent the first interface.

In some embodiments, the plurality of adhesion features are further provided in or on the semiconductor structure along a third interface with at least one insulating or conductive layer having the protective overcoating thereon.

In some embodiments, the power semiconductor device may include a Schottky junction, and where the interface is laterally between an edge termination region of the Schottky junction and the at least one edge of the semiconductor structure.

In some embodiments, the power semiconductor device may include a MOSFET, and where the interface is laterally between a metallization structure of the MOSFET and the at least one edge of the semiconductor structure.

According to some embodiments, a power semiconductor device may include a semiconductor structure may having an active region; and a protective overcoating on the active region, where a portion of the semiconductor structure that is laterally between at least one edge of the semiconductor structure and the protective overcoating may include a patterned non-planar surface.

In some embodiments, an encapsulation material may be provided directly on the patterned non-planar surface between the at least one edge of the semiconductor structure and the protective overcoating.

In some embodiments, the patterned non-planar surface may include a plurality of adhesion features that protrude from and/or are recessed in the semiconductor structure with a repeating pattern along an interface with the encapsulation material.

In some embodiments, the adhesion features are recessed in and may include portions of the semiconductor structure.

In some embodiments, the adhesion features protrude from and may include a material different than a semiconductor material of the semiconductor structure.

In some embodiments, the adhesion features have a greater adhesion strength to the encapsulation material than the semiconductor structure.

In some embodiments, the adhesion features have a greater adhesion strength to the semiconductor structure than the encapsulation material.

In some embodiments, the patterned non-planar surface may include an upper surface of the semiconductor structure that laterally extends between the at least one edge and the protective overcoating, and a side surface of the semiconductor structure that extends from the at least one edge toward a bottom surface of the semiconductor structure.

In some embodiments, the patterned non-planar surface further extends laterally between the protective overcoating and the active region.

According to some embodiments, a power semiconductor device may include a semiconductor structure; a protective overcoating on an upper surface of the semiconductor structure; and an encapsulation material on the semiconductor structure and the protective overcoating, where, per unit length, a first interface with the encapsulation material that is laterally between at least one edge of the semiconductor structure and the protective overcoating has a greater surface area than a second interface with the encapsulation material that is vertically between the at least one edge and a bottom surface of the semiconductor structure.

In some embodiments, the semiconductor structure may include a patterned non-planar surface along the first interface.

In some embodiments, the semiconductor structure further may include a second non-planar surface along the second interface.

In some embodiments, the patterned non-planar surface further extends laterally along a third interface between the protective overcoating and the semiconductor structure.

In some embodiments, the patterned non-planar surface may include a plurality of adhesion features that protrude from and/or are recessed with a repeating pattern in the semiconductor structure along the first interface.

In some embodiments, the adhesion features are recessed in and may include portions of the semiconductor structure, and/or where the adhesion features protrude from and may include a material different than a semiconductor material of the semiconductor structure.

According to some embodiments, a method of fabricating a power semiconductor device may include providing a semiconductor structure having an active region; forming a mask pattern on the semiconductor structure; performing a patterning process using the mask pattern to form one or more device patterns on or adjacent the active region, and to form adhesion features in or on the semiconductor structure laterally between the active region and at least one edge of the semiconductor structure; and forming an encapsulation material directly on the adhesion features.

In some embodiments, the adhesion features protrude from and/or are recessed in the semiconductor structure with a repeating pattern along an interface with the encapsulation material.

In some embodiments, responsive to performing the patterning process, the adhesion features are recessed in and may include portions of the semiconductor structure.

In some embodiments, a material different than a semiconductor material of the semiconductor structure may be formed on the upper surface thereof prior to forming the mask pattern thereon, where, responsive to performing the patterning process, the adhesion features protrude from and may include the material different than the semiconductor material.

In some embodiments, a first adhesion strength between the adhesion features and the encapsulation material is greater than a second adhesion strength between the semiconductor structure and the encapsulation material.

In some embodiments, a third adhesion strength between the adhesion features and the semiconductor structure is greater than the second adhesion strength.

In some embodiments, a protective overcoating may be formed on the active region of the semiconductor structure prior to forming the encapsulation material, where the protective overcoating may include a non-conductive material different from that of the encapsulation material.

In some embodiments, the interface is a first interface, and where the plurality of adhesion features protrude from and/or are recessed in the semiconductor structure with a repeating pattern along a second interface with the protective overcoating, where the second interface is laterally adjacent the first interface.

In some embodiments, the interface may include an upper surface of the semiconductor structure that extends between the active region and the at least one edge, and a side surface of the semiconductor structure that extends from the at least one edge toward a bottom surface of the semiconductor structure.

In some embodiments, an area density of the adhesion features at a corner portion of the semiconductor structure is greater than that of at least one other portion of the semiconductor structure along the interface.

In some embodiments, prior to forming the encapsulation material, the method may further include sequentially performing multiple singulation processes using saw blades having different thicknesses to form stepped portions on a side surface of the semiconductor structure that extends from the at least one edge toward a bottom surface of the semiconductor structure.

In some embodiments, the semiconductor structure may be a silicon carbide substrate and/or one or more silicon carbide epitaxial layers.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic plan view of a Schottky diode that may include adhesion features accordance with some embodiments of the present disclosure.

FIG. 1B is a schematic cross-sectional view taken along line 1B-1B of FIG. 1A.

FIG. 2A is a schematic plan view of a MOSFET that may include adhesion features accordance with some embodiments of the present disclosure.

FIG. 2B is a schematic cross-sectional view taken along line 2B-2B of FIG. 2A.

FIG. 3A is a schematic plan view of a power semiconductor device including adhesion features accordance with some embodiments of the present disclosure.

FIG. 3B is a schematic cross-sectional view taken along line 3B-3B of FIG. 3A.

FIG. 3C is an enlarged plan view illustrating a corner portion of the power semiconductor device of FIG. 3A.

FIGS. 4A, 4B, 4C, and 4D are schematic cross-sectional views illustrating power semiconductor devices including adhesion features in or on the semiconductor structure along an interface with the encapsulation, according to some embodiments of the present disclosure.

FIGS. 5A, 5B, 5C, and 5D are schematic cross-sectional views illustrating power semiconductor devices including adhesion features in or on the semiconductor structure along an interface with the encapsulation at an upper surface and along an edge of the semiconductor structure, according to some embodiments of the present disclosure.

FIGS. 6A, 6B, 6C, and 6D are schematic cross-sectional views illustrating power semiconductor devices including adhesion features in or on the semiconductor structure along a first interface with the encapsulation and along a second interface with a protective overcoating, according to some embodiments of the present disclosure.

FIG. 7 is a flow diagram illustrating methods of fabricating power semiconductor device including adhesion features in or on the semiconductor structure along an interface with the encapsulation, according to some embodiments of the present disclosure.

FIGS. 8A, 8B, 8C, 8D, 8E, 8F, and 8G are enlarged cross-sectional views illustrating example shapes of subtractive adhesion features according to some embodiments of the present disclosure.

FIGS. 9A, 9B, 9C, 9D, 9E, 9F, 9G, and 9H are enlarged cross-sectional views illustrating example shapes of additive adhesion features according to some embodiments of the present disclosure.

FIGS. 10A, 10B, 10C, 10D, 10E, and 10F are schematic plan views of a power semiconductor device including adhesion features having example patterns in accordance with some embodiments of the present disclosure.

FIG. 11A is a plan view image illustrating examples of delamination of protective overcoating layers in power semiconductor devices.

FIG. 11B is a cross-sectional view image illustrating examples of delamination propagation in power semiconductor devices.

FIG. 11C is a cross-sectional view schematically illustrating an encapsulation bonding interface in power semiconductor devices.

FIGS. 12A and 12B are enlarged plan view images illustrating portions of inactive regions between adjacent semiconductor dies.

### DETAILED DESCRIPTION

In overmold-type power semiconductor device packages, a non-conductive encapsulation structure (e.g., a mold compound, such as overmolded plastic) may completely or partially encapsulate the die on a package submount or flange. The encapsulation may differ in materials and/or characteristics as compared to the materials of non-conductive protective overcoating(s) on the active region of the semiconductor structure.

Embodiments of the present disclosure are directed to power semiconductor devices including interfaces that are configured to reduce or prevent delamination of non-conductive protective materials formed thereon, such as encapsulation and/or protective overcoating layers. The power semiconductor devices including the protective materials thereon may be discrete package devices, which may refer to packages primarily including a semiconductor die, conductive leads and lead frames, and protective materials thereon. In some embodiments, the semiconductor die may be a semiconductor structure including a semiconductor substrate and one or epitaxial layers thereon, such as silicon carbide (SiC) or GaN on SiC.

As shown in FIGS. 11A to 11C, a power semiconductor device 1100 may include a protective overcoating 152 on a semiconductor structure 120. The protective overcoating 152 may be a polymer or other non-conductive layer (e.g., polyimide), which may differ in materials and/or characteristics as compared to the materials of the semiconductor structure 120. A passivation layer 111 may extend between the protective overcoating 152 and the semiconductor structure 120. The passivation layer 111 may be an oxide-or nitride-based non-conductive layer, such as silicon nitride (SiN), silicon oxide (SiOx), silicon oxynitride (SiON). The protective overcoating 152 and/or one or more passivation layers 111 may be provided on the active region of the semiconductor structure 120 to provide electrical and/or chemical protection. Additional layers (e.g., an intermetallic dielectric layer IMD and a field oxide layer FOX) may also be provided between the semiconductor structure 120 and the passivation layer 111 or protective overcoating 152 thereon.

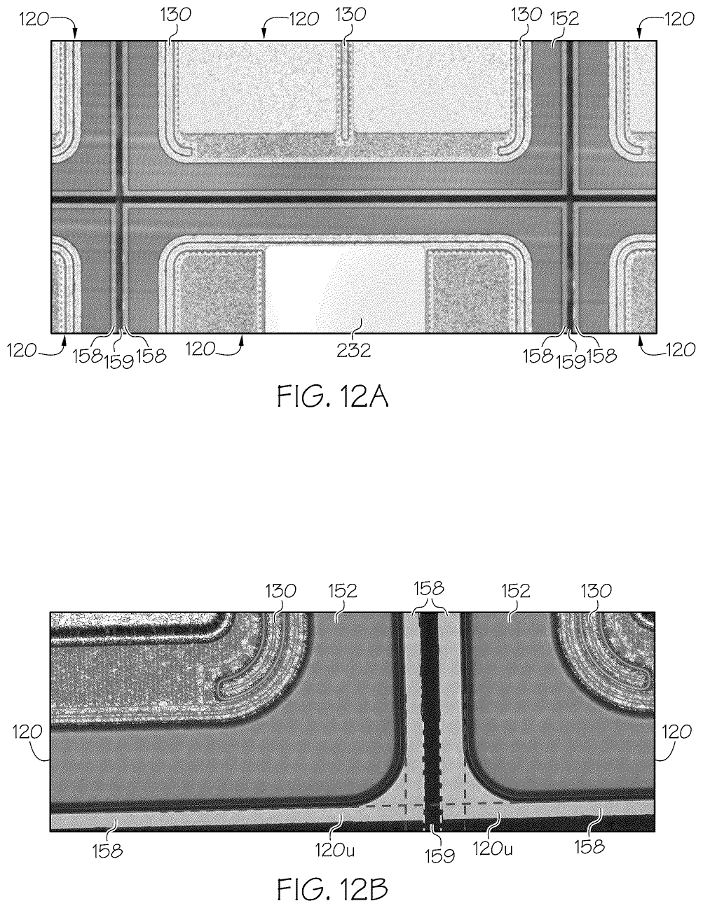

FIGS. 12A and 12B illustrate that portions of a saw street 158 (also referred to as a dicing street or scribe line) may be exposed by openings in the protective overcoating 152, for singulation. For example, a portion 159 of the saw street 158 may be removed by dicing operations to singulate adjacent portions of the semiconductor structure 120, thereby defining respective semiconductor dies. A width of the removed portion 159 may be referred to as the saw kerf, and may correspond or may be approximately equal to a width of the saw blade that is used in the dicing operations.

Still referring to FIGS. 11A to 11C, an encapsulation material or structure 150 is provided on the semiconductor structure 120. The encapsulation material or structure (generally referred to herein as encapsulation 150) may be provided on the protective overcoating 152, on an upper surface 120u (i.e., a horizontal surface) of the semiconductor structure 120 that is exposed by openings in the protective overcoating 152, and/or on side surfaces 120s (i.e., vertical surfaces) adjacent the edges 120e of the semiconductor structure 120.

The encapsulation 150 is formed from a different non-conductive material than the protective overcoating 152, and may include one or more layers of (but not limited to) silicone gels, elastomer gels, epoxy potting, elastomer potting, epoxy molding compound (EMC; including transfer molding compound and compression molding compound), thermoset plastic, and thermoplastic materials. In some embodiments, the encapsulation 150 may be free of the materials used to form the passivation layer(s) 111 and the protective overcoating 152. For example, the encapsulation 150 may be free of oxide-, nitride-, and/or polyimide-based layers.

As shown in FIG. 11B, some embodiments of the present disclosure may arise from realization that delamination of the protective overcoating 152 (e.g. a polyimide layer) along an interface between the protective overcoating 152 and the active region 14 of a semiconductor structure 120 may be initiated or exacerbated by delamination of the encapsulation 150 (e.g., a mold compound or overmold structure) along an interface 151 between the encapsulation 150 and the semiconductor structure 120. The interface 151 between the encapsulation 150 and the semiconductor structure 120 (also referred to herein as the encapsulation bonding interface) may be or may extend laterally between the active region 14 and at least one edge 120e of the semiconductor structure. For example, delamination of the mold compound may be initiated at a corner of the semiconductor die (e.g., in the saw street opening in the protective polyimide layer), and may propagate inward to break adhesion at the interface between the polyimide layer and the semiconductor die (or at the interface with the passivation layer therebetween), thereby causing lifting of the polyimide layer at the corners of the interface, particularly after temperature cycling. Delamination stress may also be highest at edges or corners of the semiconductor die, adjacent portions of the saw street that may remain after dicing or singulation of an adjacent semiconductor die from a semiconductor wafer. That is, while delamination may occur where the protective overcoating material integrity is more robust than the adhesion strength at the overcoating bonding interface with the semiconductor structure, the delamination may initiate at the encapsulation bonding interface with the semiconductor structure.

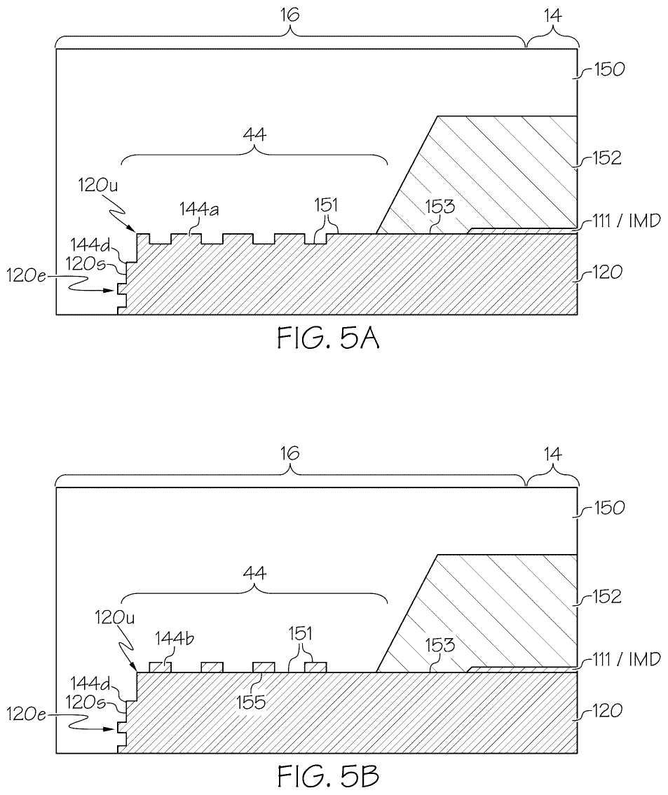

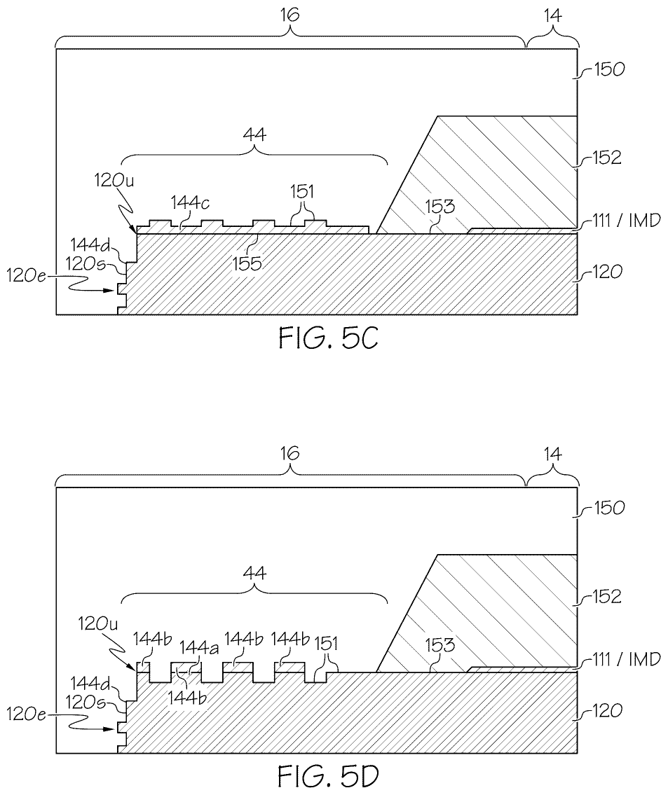

Embodiments of the present disclosure are directed to preventing delamination at the encapsulation bonding interface, which may be referred to herein as any interface between the encapsulation and one or more surfaces of the semiconductor structure (including intervening materials or features therebetween). For example, the encapsulation bonding interface 151 may extend along the upper surface 120u of the semiconductor structure 120 (e.g., laterally extending between the active region and edge 120e or corner portions that are exposed by openings in a protective overcoating 152, as shown in FIG. 11C), /d/ or side surfaces 120s of the semiconductor structure (e.g., vertically extending from the edges 120e toward a bottom surface of the semiconductor structure 120, as shown in FIGS. 5A-5C).

The encapsulation bonding interface may be or may extend laterally outside the active region of the semiconductor structure, for example, extending horizontally between the active region and at least one edge of the semiconductor structure (e.g., along the inactive region of the semiconductor structure adjacent a periphery of the active region). In some embodiments, the encapsulation bonding interface may be or may extend laterally outside of an edge termination region of the semiconductor structure, for example, extending horizontally between the edge termination region and at least one edge of the semiconductor structure (e.g., along portions of a saw street region that may remain after singulation of the semiconductor structure from a semiconductor wafer). The encapsulation bonding interface may include a surface of the semiconductor structure (for example, epitaxial layers having portions that provide the drift region) and/or features formed on the semiconductor structure to which the encapsulation is attached.

In particular, embodiments of the present disclosure provide designed topology structures (also referred to herein as adhesion features) that are configured to increase adhesion between the encapsulation and the semiconductor structure by providing patterned non-planar features (including protruding and/or recessed features with a geometric and/or repeating pattern that provide increased surface roughness or mechanical interlocking) or otherwise increasing the surface area of contact between the encapsulation and the semiconductor structure along the encapsulation bonding interface (particularly along the edge and/or corner portions of the semiconductor structure). That is, the adhesion features may include designed structures provided in a repeating pattern (including periodic patterns with a constant pitch or spacing between features, or aperiodic patterns with a variable pitch or spacing between features) in or on the semiconductor structure, for example, adjacent edges and/or corners of the semiconductor structure that are exposed by openings in the protective overcoating (e.g., in the saw street region), to increase the surface area of the encapsulation bonding interface. The adhesion features may be additive (e.g., protrusions of a different material than the semiconductor structure and deposited or otherwise patterned thereon) and/or subtractive (e.g., recesses etched or otherwise formed in the epitaxial layer or other semiconductor material layer of the semiconductor structure). The adhesion features may define geometric shapes in cross-section and/or in plan view. Adhesion features as described herein may thereby reduce and/or prevent delamination propagation that may be initiated at the encapsulation bonding interface.

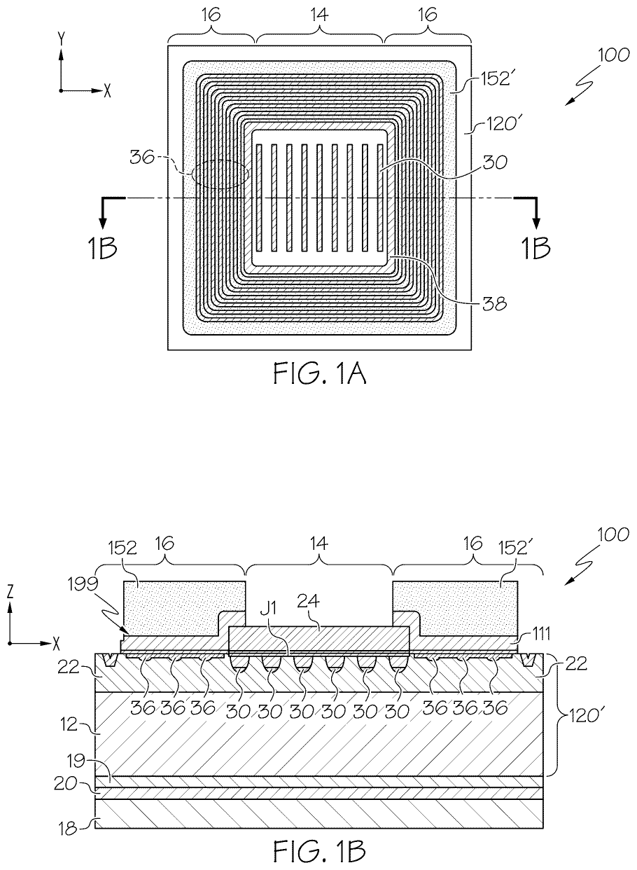

FIG. 1A is a schematic plan view of a power semiconductor device 100 that may include adhesion-enhancing features accordance with some embodiments of the present disclosure. FIG. 1B is a schematic cross-sectional view of the power semiconductor device 100 taken along line 1B-1B of FIG. 1A. In FIGS. 1A and 1B, the power semiconductor device 100 is illustrated as a Schottky diode implemented in a semiconductor structure 120′by way of example. The Schottky diode 100 has a “unit cell” structure in which the active region includes a plurality of individual diodes that are disposed in parallel to each other and that together function as a single power Schottky diode.

As shown in FIGS. 1A and 1B, the Schottky diode 100 includes a substrate 12 in which an active region 14 within an edge termination region 16 is defined. The edge termination region 16 may help reduce undesired electric field crowding effects that may occur at the edges of the active region 14, and may more generally be referred to as an inactive region 16. The edge termination region 16 may, but does necessarily, completely or substantially surround the active region 14. A drift layer 22 extends along the top side of the substrate 12 to define the semiconductor structure 120′. The substrate 12 may be a wide band-gap semiconductor substrate. In the example Schottky diode 100, the substrate 12 and the drift layer 22 are silicon carbide (SiC)-based, but are not limited thereto.

A cathode contact 18 extends along the bottom of the substrate 12 below both the active region 14 and the edge termination region 16. The cathode contact may be formed of titanium (Ti), nickel (Ni), and/or silver (Ag) in some embodiments. One or more cathode ohmic layers 19, 20 may be provided between the substrate 12 and the cathode contact 18 to facilitate a low impedance coupling therebetween. The cathode ohmic layer(s) may include one or more layers of ohmic metal, such as a nickel (Ni) layer 20 and a nickel silicide (NiSi) layer 19. While not shown, one or more additional layers may be formed on the cathode contact 18 to define a backside metal stack for attachment to a package submount. The drift layer 22 and the cathode contact 18 may extend along both the active region 14 and the edge termination region 16 on opposite sides of the substrate 12.

In the active region 14, a Schottky metal layer 24 is provided on the top surface of the drift layer 22 to define a metal-semiconductor junction J1, which provides a Schottky barrier and is created between the metal layer 24 and the doped semiconductor drift layer 22. The Schottky metal layer 24 may be formed of titanium (Ti), tantalum (Ta), and/or aluminum (Al) in some embodiments. The Schottky diode 100 may function as a traditional p-n diode by passing current in the forward-biased direction and blocking current in the reverse-biased direction; however, the Schottky barrier provided at the metal-semiconductor junction J1 provides advantages including a lower barrier height (which correlates to lower forward voltage drops and a smaller forward turn-on voltage), and lower capacitance (which can allow for higher switching speeds).

An anode contact (not shown) may be formed on the Schottky layer 24. In the illustrated embodiment, the substrate 12 is heavily doped and the drift layer 22 is relatively lightly doped, e.g., with an N-type or P-type material. The drift layer 22 may be substantially uniformly doped or doped in a graded fashion, e.g., from being relatively more heavily doped proximate the substrate 12 to being more lightly doped proximate the Schottky layer 24.

Beneath the Schottky layer 24, a plurality of junction-barrier (JB) elements 30 are provided along the top surface of the drift layer 22. For example, the JB elements 30 may be formed by selectively doping respective regions in the drift layer 22 (illustrated by way of example as elongated stripes 30 in FIG. 1A) with a doping material of an opposite conductivity type than the drift layer 22. Regions of metal-semiconductor contact between JB elements 30 (that is, any metal-semiconductor junction between the Schottky layer 24 and portions of the top surface of the drift layer 22 that do not have a JB element 30) may be referred to as Schottky junctions J1, while p-n junctions between a JB element 30 and the drift layer 22 may be referred to as a JB junctions. When the Schottky diode 100 is reverse-biased, depletion regions that form adjacent the JB elements 30 expand to block reverse current through the Schottky diode 100, thereby protecting the Schottky junction and limiting reverse leakage current.

As shown in FIGS. 1A and 1B, the edge termination region 16 includes a plurality of concentric guard rings 36. The guard rings 36 may be formed by heavily doping the corresponding portions of the recessed portions of the drift layer 22 with a doping material of an opposite conductivity type than the drift layer 22. While illustrated as substantially rectangular, the edge termination region 16 and the guard rings 36, may be of any shape and will generally correspond to the shape of the periphery of the active region 14, which is rectangular in the illustrated embodiments. Each of these elements may continuously or discontinuously extend around the active region 14. Also, it will be understood that edge termination structures other than guard rings 36 may be used.

One or more passivation layers 111 may be formed on the edge termination region 16 and may extend on edges of the Schottky layer 24. The passivation layers 111 may be nitride-based, such as silicon nitride (SiN), and may function as a conformal coating that protects the underlying layers from adverse environmental conditions. In the examples of FIGS. 1A and 1B, the passivation layers 111 define portions of a bonding surface of the semiconductor structure 120′. For further protection against damage (e.g. arcing, moisture, etc.), a protective overcoating (e.g., a polyimide layer) 152′is provided on the bonding surface.

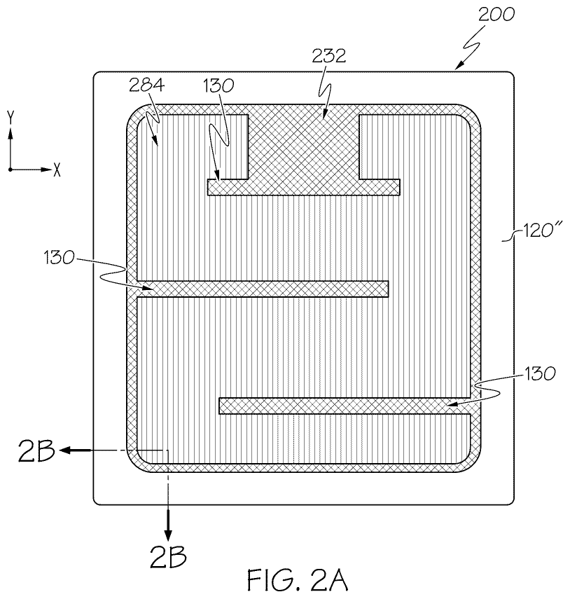

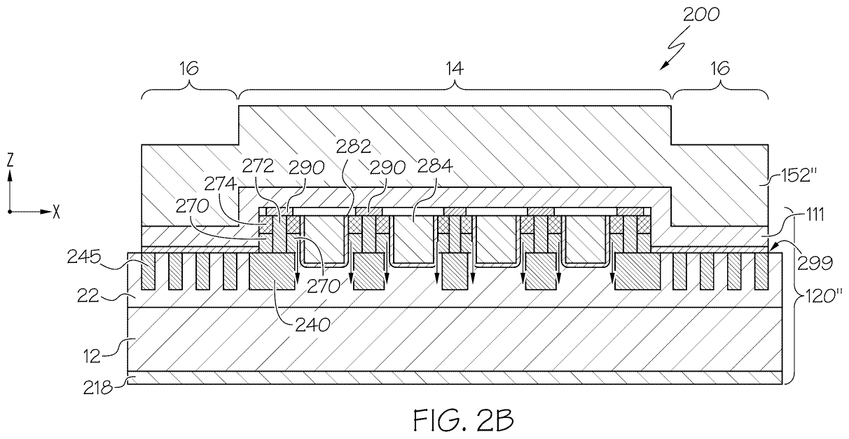

FIG. 2A is a schematic plan view of a power semiconductor device 200 that may include adhesion-enhancing features accordance with some embodiments of the present disclosure. FIG. 2B is a schematic cross-sectional view of the power semiconductor device 200 taken along line 2B-2B of FIG. 2A. It will be appreciated that specific layer structures, doping concentrations, materials, conductivity types and the like that are shown in FIGS. 2A-2B and/or described below are merely provided as examples for purposes of illustration rather than limitation.

In FIGS. 2A and 2B, the power semiconductor device 200 is illustrated as a MOSFET by way of example. The MOSFET 200 has a “unit cell” structure in which the active region includes a plurality of individual MOSFETs that are disposed in parallel to each other and that together function as a single power MOSFET. The power MOSFET 200 includes a substrate 12 in which an active region 14 within an edge termination region 16 (or more generally, an inactive region 16) is defined. The edge termination region 16 may help reduce undesired electric field crowding effects that may occur at the edges of the active region 14. The edge termination region 216 may, but does necessarily, completely or substantially surround the active region 14. A drift layer 22 extends along the top side of the substrate 12 to define the semiconductor structure 120″.

The substrate 12 may be a wide band-gap semiconductor substrate. In the example power MOSFET 200, the substrate 12 and the drift layer 22 are silicon carbide (SiC)-based, for example, a SiC substrate 12 and a SiC drift layer 22 epitaxially grown thereon with a uniform or graded doping concentration. The substrate 12 and the drift layer 22 are not limited to SiC, and may be formed from other material systems, such as, for example, Group III nitrides (e.g., GaN), gallium arsenide (GaAs), silicon (Si), germanium (Ge), silicon germanium (SiGe), and the like. The drift layer 22 may be substantially uniformly doped or doped in a graded fashion, e.g., from being relatively more heavily doped (e.g., to define a current spreading layer) proximate the substrate 12 to being more lightly doped opposite the substrate 12. The edge termination region 16 substantially surrounds the active region 14, and may be recessed (as illustrated) or coplanar relative to the top surface of the drift layer 22. The edge termination region 16 includes a plurality of guard rings 36. The guard rings 36 may be formed by heavily doping the corresponding portions of the recessed portions of the drift layer 22 with a doping material of an opposite conductivity type than the drift layer 22. However, it will be understood that edge termination structures other than guard rings 36 may be used.

Spaced apart shielding regions 240 may be formed in the upper surface of the drift layer 22 in the active region 14, and gate trenches 280 are formed extending through well regions 270 in the drift layer 22. The gate trenches 280 may have a U-shaped cross-section in some embodiments, as shown in FIG. 2B. A gate insulating layer 282 such as a silicon oxide layer is formed on the bottom surface and sidewalls of each gate trench 280. A gate electrode 284 is formed on the gate insulating layer 282 in the respective gate trenches 280. The gate electrodes 284 may comprise, for example, a semiconductor or a metal material. Heavily-doped silicon carbide source regions 274 may be formed in upper portions of the well regions 270. Source contacts 290 (e.g., ohmic contacts) may be formed on the heavily-doped n-type source region 274. The source contacts 290 may be electrically connected to one another (e.g., by a top side metallization or other metal overlayers or other metal overlayers, which are electrically isolated from the gate buses 130 and gate pad 232) to form a single source electrode, and may be electrically connected to the shielding regions 240 (e.g., by respective regions 272).

The drift region 22 and the substrate 12 together act as a common drain region for the power MOSFET 200. A drain contact 218 may be formed on the lower surface of the substrate 212 below both the active region 14 and the edge termination region 16. While not shown, one or more additional layers may be formed on the drain contact 218 to define a backside metal stack for attachment to a package submount. The backside metal stack may include, but is not limited to, multi-layer metal stacks including titanium (Ti), titanium tungsten (TiW), gold (Au), platinum (Pt), nickel (Ni), and/or aluminum (Al).

As shown in FIG. 2A, a gate bond pad 232 may be electrically connected to each gate electrode or gate finger 284 by a gate electrode pattern 130. The gate electrode pattern 130 may provide one or more gate buses that electrically connect the gate fingers 284 to the gate bond pad 232. The gate electrode pattern 130 may comprise, for example, a polysilicon pattern in some embodiments, although metal or other conductive patterns could also be used.

Still referring to FIG. 2A, the MOSFET 200 includes a top-side metallization structure that electrically connects source regions in the semiconductor structure 120″ of the MOSFET 200 to an external device. The top-side metallization structure is not shown in FIG. 2A, as significant portions of the top-side metallization structure are covered by one or more passivation layers 111 and a protective overcoating 152″. The passivation layer(s) 111 may be nitride-based (e.g., a SiN layer), and may function as a conformal coating that protects the underlying layers from adverse environmental conditions, and may define portions of a bonding surface of the semiconductor structure 120″. A protective overcoating (e.g., a polyimide layer) 152″ is provided on the bonding surface, for further protection against damage (e.g., arcing, moisture, etc.). The polyimide layer or other protective overcoating 152″ may protect the semiconductor structure 120″ underneath, and may provide a leveling effect for appropriate handling in following manufacturing steps. Source bond pads (not shown) may be portions of the top-side metallization structure that are exposed through openings in the protective overcoating 152″ in some embodiments. Bond wires (not shown) may be used to connect the gate bond pad 232 and the source bond pads to external circuits or the like.

Differences or mismatch in the coefficients of thermal expansion (CTE) of the materials of the semiconductor structure 120′, 120″ (collectively, 120) and the layers formed thereon (e.g., the protective overcoating 152′, 152″ (collectively, 152) and/or an encapsulation or mold compound 150) can contribute to different levels of thermomechanical stress. Such stress differences may result in delamination of one or more layers 150 from the semiconductor structure 120. In particular, as noted above, delamination of the protective overcoating 152 along an interface between the protective overcoating 152 and the active region 14 of a semiconductor structure 120 may be initiated by delamination of the encapsulation 150 along an interface 151 between the encapsulation 150 and the semiconductor structure 120. In some embodiments of the present disclosure, adhesion at the interface 151 between an encapsulation material 150 and the semiconductor structure 120 is improved by increasing the bonding or contact surface area at the interface 151 using adhesion features as described herein.

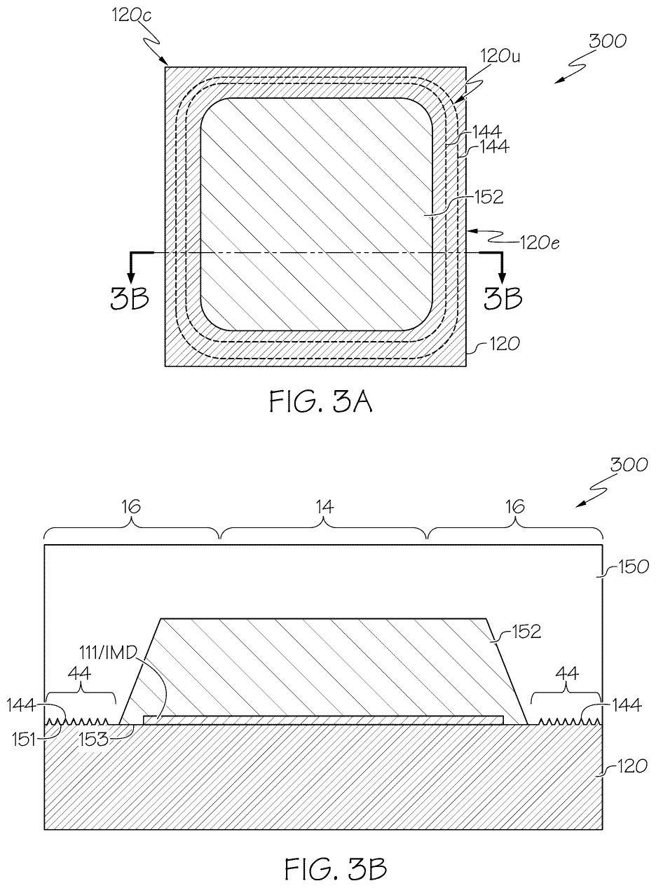

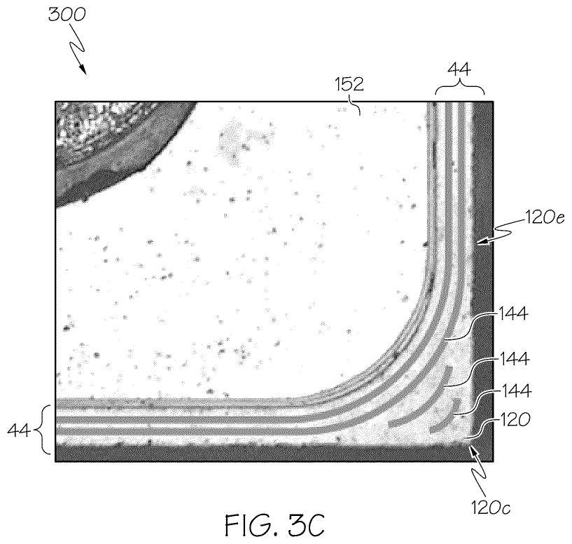

FIG. 3A is a schematic plan view of a power semiconductor device including adhesion features accordance with some embodiments of the present disclosure. FIG. 3B is a schematic cross-sectional view taken along line 3B-3B of FIG. 3A. FIG. 3C is an enlarged plan view illustrating a corner portion of the power semiconductor device of FIG. 3A.

As shown in FIGS. 3A to 3C, a power semiconductor device 300 (for example, the Schottky diode 100 or the MOSFET 200) includes a semiconductor structure 120 and an encapsulation material 150 (e.g., a mold compound or overmold structure; more generally referred to herein as an encapsulation material or structure) on the semiconductor structure 120. The semiconductor structure 120 may include a semiconductor substrate 12 and one or more semiconductor layers 22 (such as epitaxial layers defining a drift region and/or passivation layers thereon) on the substrate 12. In some embodiments, the semiconductor structure 120 may include substrates and/or layers that are silicon carbide-based or Group III nitride-based (e.g., GaN-based).

The semiconductor structure 120 includes an active region 14 and an inactive region 16 (which may include an edge termination region and/or portions of a saw street or other singulation region) extending between the active region 14 and the edge 120e of the semiconductor structure 120. A protective overcoating 152 is provided on a the active region 14 of the semiconductor structure 120. The protective overcoating 152 may include one or more non-conductive layers, such as polymer layer(s). In some embodiments, the protective overcoating 152 may be a polyimide layer; however, other examples of materials for the protective overcoating 152 include, but are not limited to, polybenzoxazole (PBO) and benzocyclobutene (BCB).

The encapsulation material 150 is formed on the protective overcoating 152 and on an upper surface 120u of the semiconductor structure 120 exposed thereby. In some embodiments, the encapsulation 150 may be directly on the semiconductor structure 120 along the interface 151. The protective overcoating 152 may be laterally adjacent to the encapsulation material 150 and exposes the interface 151. The encapsulation material 150 comprises a non-conductive material that is different from the protective overcoating 152. For example, The encapsulation material 150 may include one or more layers of (but not limited to) silicone gels, elastomer gels, epoxy potting, elastomer potting, epoxy molding compound (EMC; including transfer molding compound and compression molding compound), thermoset plastic, and thermoplastic materials.

As such, the power semiconductor device 300 may include a first interface 151 (also referred to herein as the encapsulation bonding interface 151) between the encapsulation 150 and the semiconductor structure 120 in the inactive region 16, and a second interface 153 (also referred to herein as the overcoating bonding interface 153) between the protective overcoating 152 and the semiconductor structure 120 in the active region 14. The first interface 151 extends laterally between the active region 14 and at least one edge 120e or corner 120c of the semiconductor structure 120. For example, the first interface 151 may extend along the upper surface 120u of the semiconductor structure 120 (e.g., laterally extending between the active region 14 and edge 120e or corner 120c portions that are exposed by openings in the protective overcoating 152, and/or along side surfaces 120s of the semiconductor structure 120 (e.g., vertically extending from the edges 120e toward a bottom surface of the semiconductor structure 120). Depending on the specific type of power semiconductor device, the interface 151 may be situated laterally between an edge termination region 16 of a Schottky junction (as shown in FIGS. 1A-1B) or a metallization structure of a MOSFET and the at least one edge 120e of the semiconductor structure 120 (as shown in FIGS. 2A-2B).

As noted above, delamination of the protective overcoating 152 along the second interface 153 between the protective overcoating 152 and the semiconductor structure 120 in the active region 14 may be initiated or exacerbated by delamination of the encapsulation 150 along the first interface 151 between the encapsulation 150 and the semiconductor structure 120. The power semiconductor device 300 thus includes a patterned non-planar surface 44 on a portion of the semiconductor structure 120 that is laterally between at least one edge 120e of the semiconductor structure 120 and the protective overcoating 152. The encapsulation material 150 may be directly on the patterned non-planar surface 44. As used herein, a “patterned” non-planar surface may include a regular or repeating (e.g., periodic or aperiodic) pattern, rather than a random pattern. For example, the patterned non-planar surface 44 may include a plurality of adhesion features 144 that are in or on the semiconductor structure 120 along the interface 151 with the encapsulation material 150.

The adhesion features 144 may protrude from or may be recessed into the semiconductor structure 120 along the interface 151. In some embodiments, the adhesion features 144 are recessed into the semiconductor structure 120 and include portions of the semiconductor material itself, also referred to as subtractive features. Alternatively, the adhesion features 144 may protrude from the semiconductor structure 120 and be composed of a material that is different from the semiconductor material of the semiconductor structure 120, also referred to as additive features.

The adhesion features 144 are configured to enhance the bonding strength between the encapsulation material 150 and the semiconductor structure 120. The adhesion features 144 may be provided in various shapes, such as a patterned “dimple” structure (as shown in FIG. 3A) or a continuous arc or ring (as shown in FIG. 3C), to provide mechanical interlocking and improved adhesion.

The adhesion strength between the adhesion features 144 and the encapsulation material 150 is greater than the adhesion strength between the (non-patterned) semiconductor structure 120 and the encapsulation material 150. That is, the adhesion features 144 may be configured to provide a first adhesion strength to the encapsulation material 150, while the semiconductor structure 120 may have a second adhesion strength to the encapsulation material 150, where the first adhesion strength is greater than the second adhesion strength.

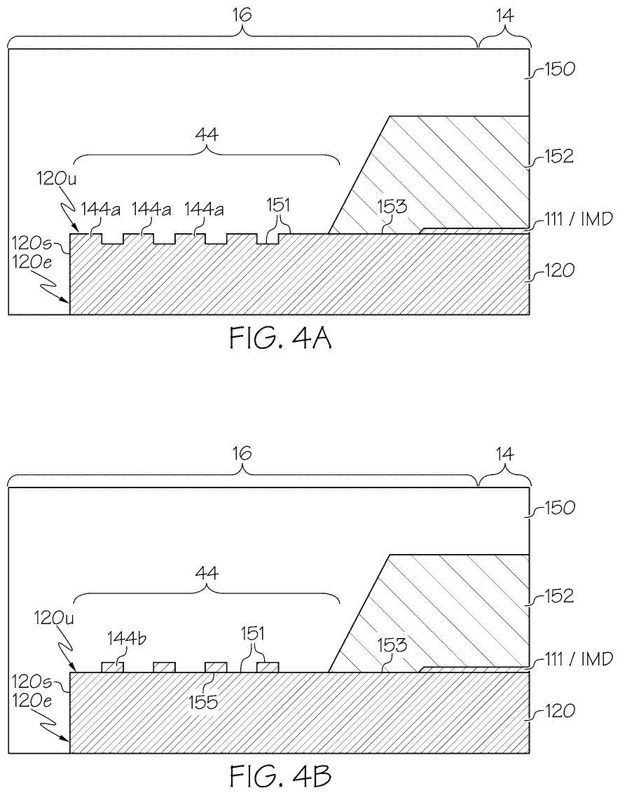

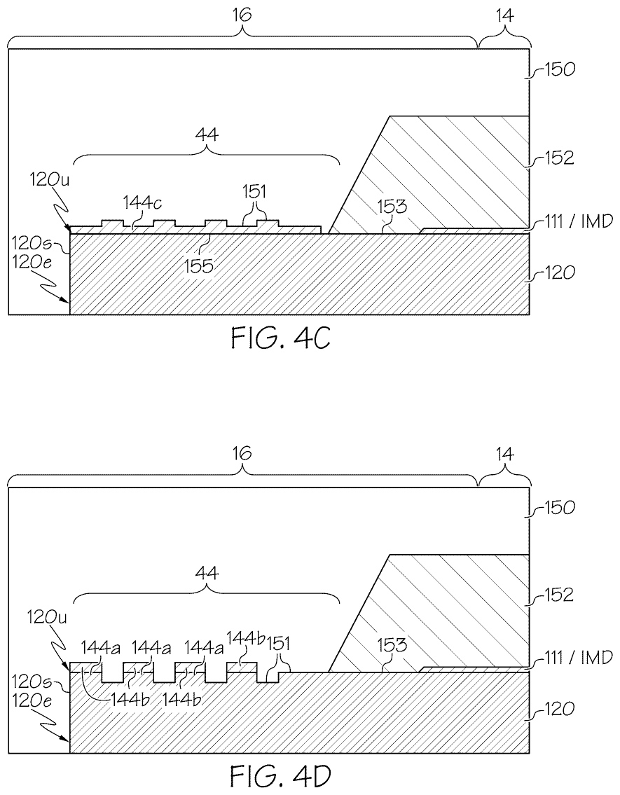

More generally, the patterned non-planar surface 44 includes a repeating or non-random arrangement of features and/or materials that are configured to increase a contact surface area or otherwise increase adhesion strength along the interface 151 between the encapsulation 150 and the surface of the semiconductor structure 120 (e.g., as compared to a planar surface area between the encapsulation 150 and the surface of the semiconductor structure 120). Specific (non-limiting) examples of adhesion features 144 in accordance with embodiments of the present disclosure are discussed below with reference to FIGS. 4A to 6C.

FIGS. 4A, 4B, 4C, and 4D are schematic cross-sectional views illustrating power semiconductor devices including adhesion features 144a, 144b, and 144c in or on the semiconductor structure 120 along the interface 151 with the encapsulation 150, according to some embodiments of the present disclosure.

As shown in FIG. 4A, subtractive adhesion features 144a are formed in the upper surface 120u of the semiconductor structure 120 laterally extending between the active region 14 (or the protective overcoating 152 thereon) and the edge 120e. For example, the subtractive adhesion features 144 may be formed using an etching process to define a continuously extending pattern (e.g., trenches extending in a continuous ring or in discontinuous segments or arcs) or a discontinuously extending pattern (e.g., a plurality of holes or openings in the semiconductor structure 120, also referred to as a recessed dimple pattern).

As shown in FIGS. 4B and 4C, additive adhesion features 144b and 144c are formed on a surface of the semiconductor structure 120 laterally extending between the active region 14 (or the protective overcoating 152 thereon) and the edge 120e. For example, the additive adhesion features 144b, 144c may be formed by forming and pattering one or more intermediary materials or layers 140 on the surface of the semiconductor structure 120 to define a continuously extending pattern (e.g., tracks extending in a continuous ring or in discontinuous segments or arcs) or a discontinuously extending pattern (e.g., a plurality of protrusions or dots, also referred to herein as a protruding dimple pattern). In FIG. 4B, the intermediary material 140 may be patterned to expose the surface of the semiconductor structure 120 between the adhesion features 144b. In FIG. 4C, the intermediary material 140 may be patterned such that portions of the intermediary material remain between the adhesion features 144c. In FIG. 4D, both the intermediary material 140 and the underlying surface 120u may be patterned to form adhesion features 144a, 144b that include a combination of the additive features 144b and the subtractive features 144a. That is, the intermediary layer(s) 140 may be completely etched (in FIG. 4B), partially etched (in FIG. 4C), or over etched (in FIG. 4D) to define the adhesion features 144a, 144b, and/or 144c. The additive adhesion features 144b, 144c may be formed, for example, of oxide, nitride, polysilicon, and/or metal (e.g., Al). The additive adhesion features 144b, 144c may be formed by sputtering, PECVD, and masking/etching operations.

In some embodiments, the encapsulation bonding interface may include both additive 144b, 144c and subtractive 144a adhesion features. For example, in forming and patterning the intermediary material 140 using a deposition and etching process, the etching process may etch through the intermediary material 140 to define the additive adhesion features 144b, and into the upper surface of the semiconductor structure 120 (i.e., the upper surface may be over-etched) to define the subtractive adhesion features 144a.

The adhesion strength between the additive adhesion features 144a, 144b, 144c and the semiconductor structure 120 may be greater than the adhesion strength between the (non-patterned) semiconductor structure 120 and the encapsulation material 150. That is, the adhesion features 144a, 144b, 144c may be configured to provide a third adhesion strength (between the adhesion features 144a, 144b, 144c and the semiconductor structure 120 along a third interface 155) that is greater than the second adhesion strength (between the encapsulation 150 and the semiconductor structure 120). In some embodiments, the third adhesion strength (along the third interface 155 between the adhesion features 144 and the semiconductor structure 120) may be greater than the first adhesion strength (along the first interface 151 between the adhesion features 144 and the encapsulation 150), or vice versa.

While illustrated in FIGS. 4A to 4D as being provided on the upper surface 120u of the semiconductor structure 120 between the protective overcoating 152 and the edge 120e, the non-planar patterned surface 44 may be further provided along additional surfaces. For example, in some embodiments, the adhesion features may be provided on the upper surface 120u of the semiconductor structure having the polyimide (or other protective layer) thereon, and on a side surface 120s of the semiconductor structure 120. Also, an area density of the adhesion features 144 may vary on different regions of the semiconductor structure 120 (e.g., with a higher area density of adhesion features 144 adjacent corner regions 120c of the upper surface 120u than along laterally extending edge regions 120e, as delamination stress may be comparatively higher at the corner regions 120c).

FIGS. 5A, 5B, 5C, and 5D are schematic cross-sectional views illustrating power semiconductor devices including adhesion features 144a, 144b, and 144c in or on the semiconductor structure 120 along the first interface 151 with the encapsulation 150 at the upper surface 120u, in combination with adhesion features 144d along the side surface 120s of the semiconductor structure, according to some embodiments of the present disclosure. As shown in FIGS. 5A, 5B, 5C, and 5D the adhesion features 144a, 144b, and/or 144c are formed in or on the upper surface 120u of the semiconductor structure 120 between the active region 14 (or the protective overcoating 152) and the edge 120e in continuous or discontinuous patterns, as similarly described with reference to FIGS. 4A to 4D. In addition, adhesion features 144d are formed in the side surface 120s of the semiconductor structure 120 extending from the edge 120e to a bottom surface of the semiconductor structure 120. For example, a dicing or other singulation operation may be performed in multiple steps (using sawing blades with different thicknesses) to form the adhesion features as stepped surfaces 144d along the edge 120e of the semiconductor structure 120. That is, the first interface 151 where the adhesion features 144 are located may include an upper surface 120u of the semiconductor structure 120 that extends between the active region 14 and the at least one edge 120e, as well as a side surface 120s of the semiconductor structure 120 that extends from the at least one edge 120e toward a bottom surface of the semiconductor structure 120.

In some embodiments, the adhesion features 144a, 144b, 144c may be provided along a majority or an entirety of the upper surface 120u of the semiconductor structure, that is, in or on the inactive region 16 adjacent the edge regions 120e of the upper surface 120u (e.g., along the first interface 151) and in or on the active region 14 at central regions of the semiconductor structure 120 having the polyimide or other protective overcoating 152 thereon (e.g., along the second interface 153).

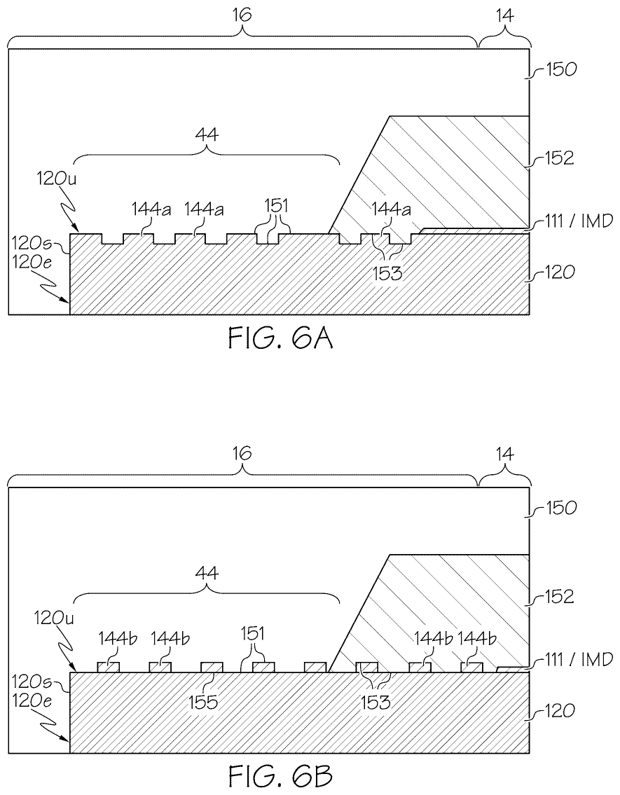

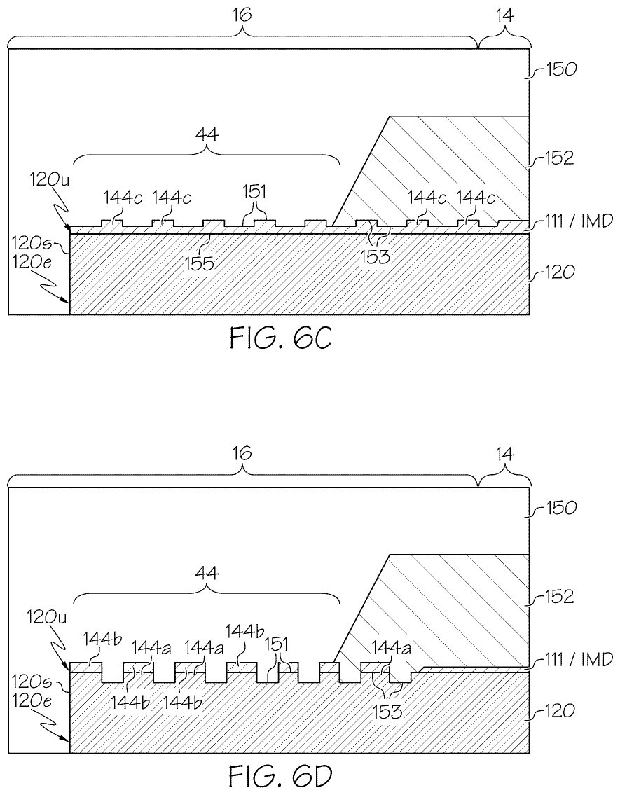

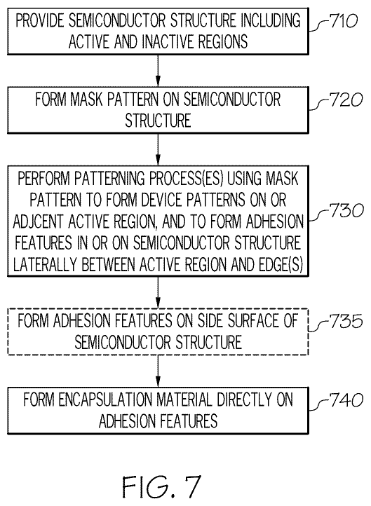

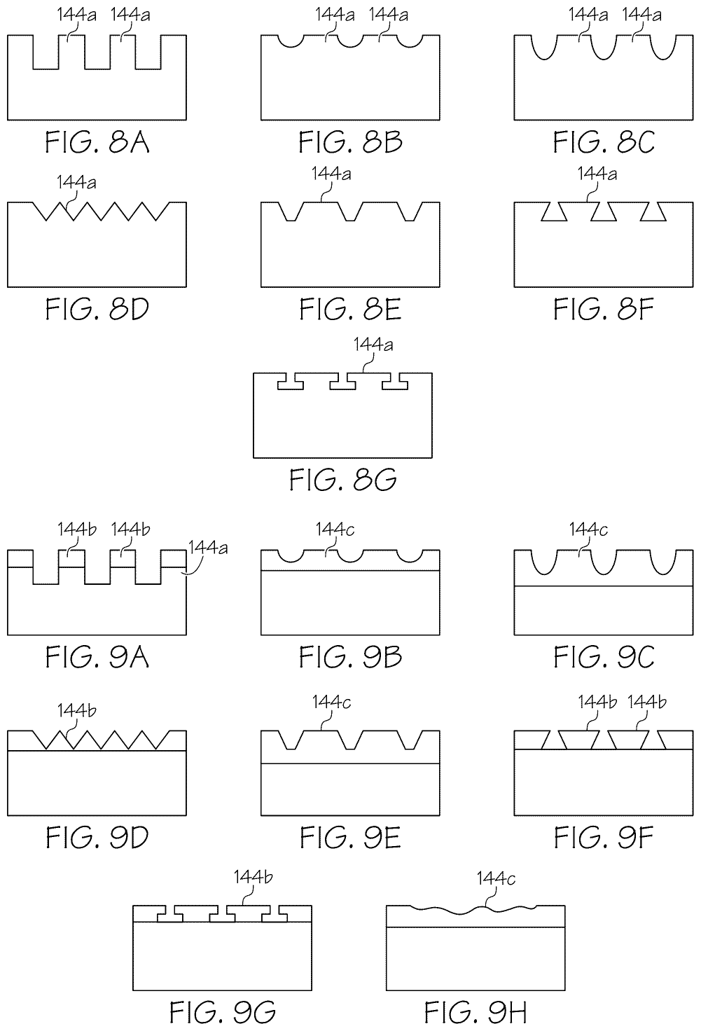

FIGS. 6A, 6B, 6C, and 6D are schematic cross-sectional views illustrating power semiconductor devices including adhesion features 144a, 144b, and/or 144c in or on the semiconductor structure 120 along the first interface 151 with the encapsulation 150 at the upper surface 120u and at least partially along the second interface 153 with the protective overcoating 152, according to some embodiments of the present disclosure. As shown in FIGS. 6A to 6D, the adhesion features 144a, 144b, and 144c are formed in or on the upper surface 120u of the semiconductor structure 120 in continuous or discontinuous patterns, using similar deposition, etching, and/or masking operations as described with reference to FIGS. 4A to 4D. The adhesion features 144a, 144b, and 144c are formed not only in or on portions of the upper surface 120u in the inactive region 16 (on which the encapsulation 150 is formed), but also on portions of the upper surface 120u extending on the active region 14 (or otherwise on which the protective overcoating 152 is formed). The subset of the adhesion features 144a, 144b, and/or 144c extending under the protective overcoating 152 (e.g., as etched into the upper surface 120u and/or as deposited and patterned on the upper surface 120u) may be configured to further increase adhesion strength with the protective overcoating 152 so as to reduce or prevent lifting of the protective overcoating 152. In addition, the subset of the adhesion features 144a, 144b, and/or 144c may be configured to further increase adhesion strength with insulating or conductive layers under the protective overcoating, such as passivation layers 111 or gate runners of the gate electrode pattern 130. That is, the adhesion features 144a, 144b, and/or 144c may be formed along the first interface 151 between the semiconductor structure 120 and the encapsulation 150, and along the second interface 153 between the semiconductor structure 120 and the protective overcoating 152 (including insulating or conductive layers thereunder), which is laterally adjacent to the first interface 151. Also, adhesion features 144d may be formed in the side surface 120s of the semiconductor structure 120 extending from the edge 120e to a bottom surface of the semiconductor structure 120, as described with reference to FIGS. 5A to 5D.

In any of the embodiments described herein, the adhesion features 144a, 144b, 144c, and/or 144d may be formed using the same fabrication processes (including masking, patterning, etching, and/or singulation processes) that are used in fabrication of other features of the semiconductor device or package (e.g., polysilicon features/layers, oxide features/layers, or nitride features/layers), and thus, may be performed without introducing additional processing steps. For example, as shown in the flow diagram of FIG. 7, methods of fabricating a power semiconductor device include providing a semiconductor structure 120 with an active region 14 (block 710), forming a mask pattern exposing portion(s) of the an inactive region 16 of the semiconductor structure 120 (block 720), and performing one or more patterning processes using the mask pattern to create one or more device patterns in or on the upper surface 120u adjacent the active region 14 (block 730). The device patterns may be semiconductor features (e.g., polysilicon layers and/or features, such as gates), and/or insulating features (e.g., oxide or nitride layers and/or features). The patterning process (block 730) may also form adhesion features 144 in or on the semiconductor structure 120 laterally between the active region 14 and at least one edge 120e of the semiconductor structure 120. Subsequently, a non-conductive encapsulation material 150 is formed directly on the adhesion features 144 (block 740).

The adhesion features 144 may be formed recessed into the semiconductor structure 120 (e.g., to form adhesion features 144a as shown in FIGS. 4A, 5A, and 6A). For example, the patterning process(es) (block 730) may include an etching process, which may etch into the upper surface 120u of the semiconductor structure 120 to define the subtractive adhesion features 144a. Additionally or alternatively, the adhesion features 144 may be formed protruding from the semiconductor structure 120 (e.g., to form adhesion features 144b as shown in FIGS. 4B, 5B, and 6B and/or adhesion features 144c as shown in FIGS. 4C, 5C, and 6C). For example, the patterning process(es) (block 730) may include a deposition process that forms an intermediary material 140 on the upper surface 120u of the semiconductor structure 120 prior to forming the mask pattern, and an etching process, which may etch into the intermediary material 140 to define the additive adhesion features 144b and/or 144c of a different material than the semiconductor structure 120. In some embodiments, the intermediary material 140 and the upper surface 120u may be etched (i.e., over-etched) to define both the additive 144b and subtractive 144a adhesion features, as shown in FIGS. 4D, 5D, and 6D. The adhesion features 144 are formed in a regular or repeating pattern (including periodic patterns with a constant pitch or spacing between features, or aperiodic patterns with a variable pitch or spacing between features) along an interface 151 with the encapsulation material 150.

In some embodiments, a protective overcoating 152 may be formed on the active region 14 of the semiconductor structure 120 before forming the encapsulation material 150 (at block 740). The protective overcoating 152 may be a non-conductive material that is different from that of the encapsulation material 150. The adhesion features 144 may be formed along a second interface 153 with the protective overcoating 152, which is laterally adjacent to the first interface 151.

The methods may further include forming adhesion features 144d on at least one side surface 120s of the semiconductor structure 120 that extends from the edge 120e toward a bottom surface of the semiconductor structure 120 (at block 735). For example, multiple singulation processes (e.g., using saw blades of different thicknesses) may be performed to form the adhesion features 144d as stepped portions on the side surface 120s of the semiconductor structure 120.

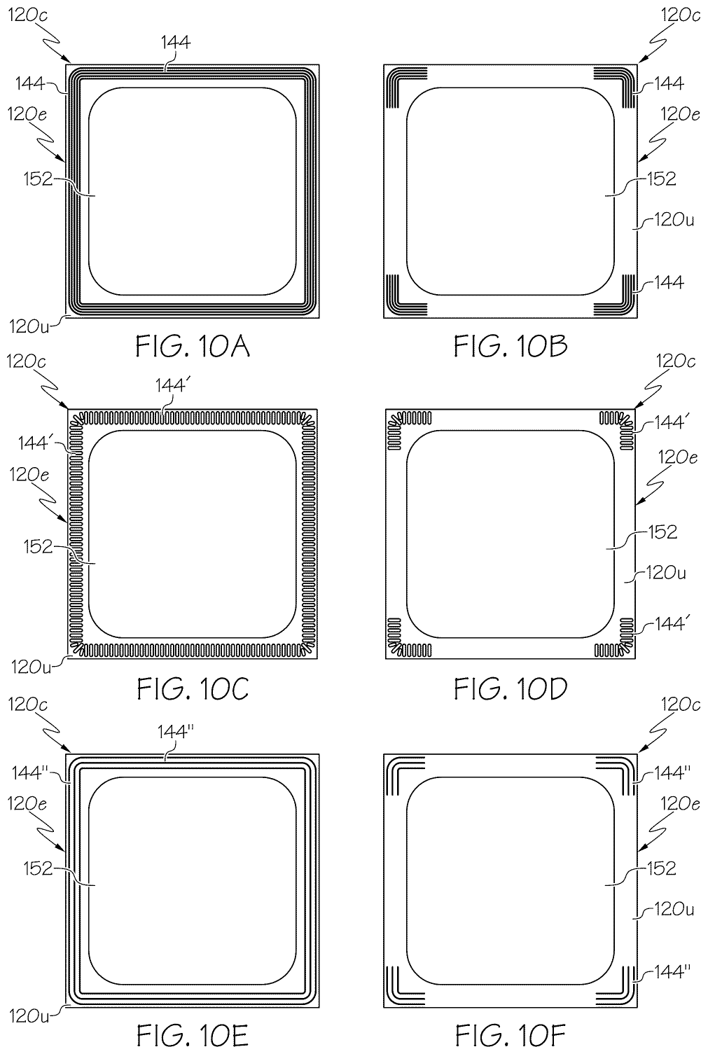

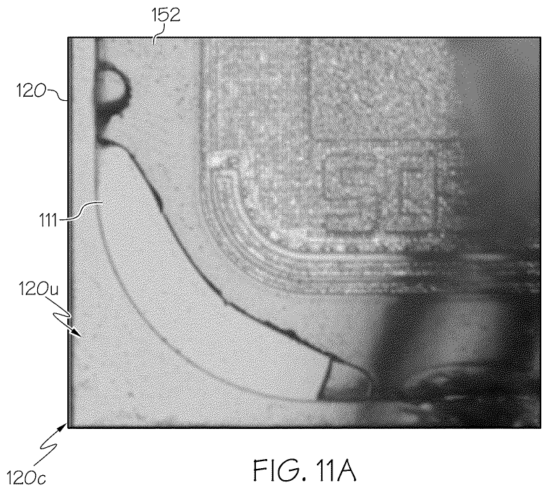

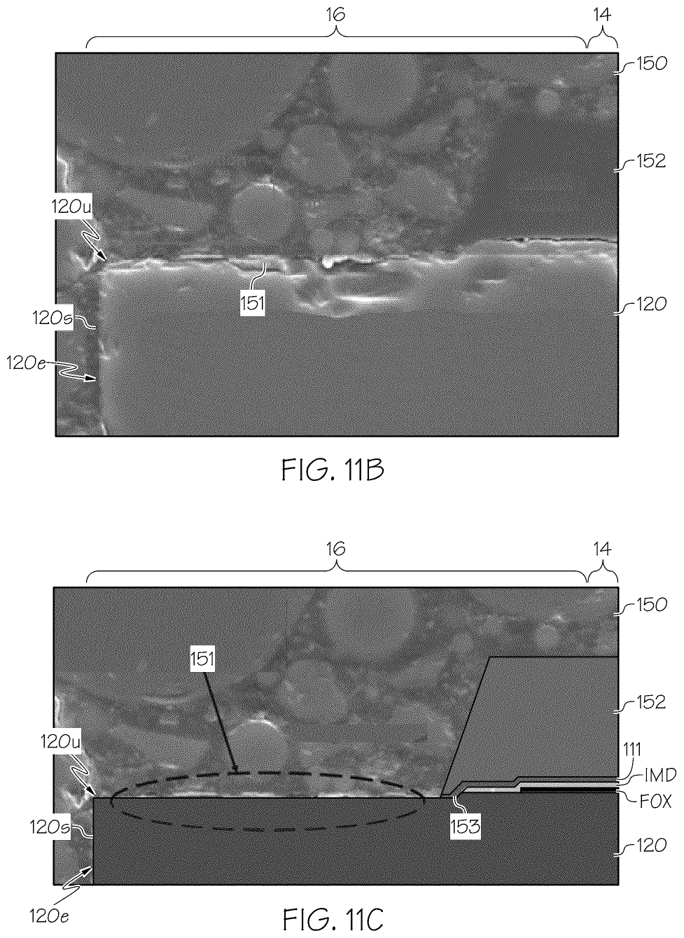

The adhesion features 144 as described herein may define various geometric shapes in cross-section (as shown in FIGS. 8A to 9H) or various geometric patterns in plan view (as shown in FIGS. 10A to 10F) that provide mechanical interlocking along the periphery of the upper surface of 120u of the semiconductor structure 120, adjacent the protective overcoating 152. In particular, FIGS. 8A, 8B, 8C, 8D, 8E, 8F, and 8G are enlarged cross-sectional views illustrating example shapes of subtractive adhesion features 144a according to some embodiments of the present disclosure. FIGS. 9A, 9B, 9C, 9D, 9E, 9F, 9G, and 9H are enlarged cross-sectional views illustrating example shapes of additive adhesion features 144b or 144c according to some embodiments of the present disclosure.

As shown in FIGS. 8A to 8G and 9A to 9H, the adhesion features 144 (whether subtractive 144a and/or additive 144b, 144c) can be provided in various cross-sectional shapes, such as rectangular, triangular, semi-elliptical, or trapezoidal. In particular, the adhesion features 144 may define respective shapes that are rectangular (in FIGS. 8A and 9A), circular (in FIGS. 8B and 9B), elliptical (in FIGS. 8C and 9C), triangular (in FIGS. 8D and 9D), trapezoidal (in FIGS. 8E and 9E), dovetail (in FIGS. 8F and 9F), slotted (in FIGS. 8G and 9G), or random (in FIG. 9H). The cross-sectional shapes of the adhesion features 144 are not limited to those specifically illustrated, and may include other suitable shapes (e.g., pyramidal, conical, rounded) of protrusions or recesses.

The adhesion features 144 having the various cross-sectional shapes may extend continuously along the encapsulation bonding interface 151 (e.g., defining ring-shaped trenches 144a that are recessed into the upper surface 120u of the semiconductor structure 120, as shown in FIGS. 8A to 8G, or ring-shaped tracks 144b, 144c of the intermediary material 140 that protrude from the upper surface 120u of the semiconductor structure 120, as shown in FIGS. 9A to 9H) or may extend discontinuously (e.g., defining arc-shaped trench segments 144a that are recessed into corner regions 120c of the upper surface 120u of the semiconductor structure 120, or arcs 144b, 144c of the intermediary material 140 that protrude from the corner regions 120c of the upper surface 120u of the semiconductor structure 120) in plan view. As shown in FIGS. 9A to 9H the intermediary layer(s) 140 may be completely etched (or over-etched) to expose portions of the semiconductor structure 120 therebetween (e.g., in FIGS. 9A, 9D, 9F, and 9G) to define the additive adhesion features 144b, or may be partially etched (in FIGS. 9B, 9C, 9E, and 9H) to define the additive adhesion features 144c.

In some embodiments, the area density of the adhesion features 144 may be greater (e.g., including more and/or more closely spaced adhesion features 144) at a corner portion 120c of the semiconductor structure 120 (where delamination stress may be highest) compared to other portions along the interface 151. Likewise, some areas or portions of the semiconductor structure 120 may be free of adhesion features 144 along the interface 151 (e.g., regions where delamination stress may be comparatively lower).

FIGS. 10A, 10B, 10C, 10D, 10E, and 10F are schematic plan views of a power semiconductor device including adhesion features 144 defining example patterns in accordance with some embodiments of the present disclosure. For example, subsets of adhesion features 144 may collectively define circular, rectangular, hexagonal, or octagonal arrangement patterns extending completely or partially around the periphery of the protective overcoating 152 in plan view. The adhesion features 144 may be uniformly provided along the encapsulation bonding interface 151 (as shown in FIGS. 10A, 10C, and 10E), or may be selectively provided in various portions of the encapsulation bonding interface 151 (e.g., at corners 120c, as shown in FIGS. 10B, 10D, and 10F), along the upper surface of 120u of the semiconductor structure 120 adjacent the periphery of the protective overcoating 152. The adhesion features 144 may extend continuously (e.g., defining trenches or tracks in ring patterns) or discontinuously (e.g., defining dashes or dots in segment or arc patterns) along the encapsulation bonding interface 151.

In particular, FIGS. 10A and 10B illustrate adhesion features 144 having longitudinal axes that extend parallel to edges 120e of the semiconductor structure 120, defining continuous ring and segment/arc shapes, respectively. FIGS. 10C and 10D illustrate adhesion features 144′ having longitudinal axes that extend perpendicular or orthogonal to edges 120e of the semiconductor structure 120, defining ring and segment/arc patterns, respectively. FIGS. 10E and 10F illustrate adhesion features 144″ having dot shapes axes that are distributed along edges 120e of the semiconductor structure 120, defining ring and segment/arc patterns, respectively.

As shown in FIGS. 10B, 10D, and 10F, an area density of the adhesion features 144 may vary on different regions of the semiconductor structure 120. For example, the adhesion features 144, 144′, 144″ may be provided with higher or greater area density adjacent corner regions 120c of the upper surface 120u than along laterally extending edge regions 120e, as delamination stress may be comparatively higher or more concentrated at the corner regions 120c. In particular, as shown in FIGS. 10B, 10D, and 10F, the adhesion features 144, 144′, 144″ may be selectively provided at corner regions 120c of the upper surface 120u of the semiconductor structure 120, while areas of the upper surface 120u between the corners 120c may have a lower density of adhesion features 144, 144′, 144″ (or, as shown, may be free of the adhesion features 144, 144′, 144″).

As described herein, providing the adhesion features 144 along the encapsulation bonding interface 151 may prevent not only delamination of the encapsulation 150 from the semiconductor structure 120 at the edges 120e or corners 120c, but may also prevent delamination at other interfaces, for example, at the interface 153 between the protective overcoating 152 (e.g., polyimide) and the active region 14 of the semiconductor structure 120, and/or at an interface between the protective overcoating 152 and a passivation layer 111 (e.g., nitride). In some embodiments, the adhesion features 144 may be further provided along such other interfaces (e.g., along the interface 153 between the protective overcoating 152 and the semiconductor structure 120, and/or along the interface between the protective overcoating 152 and a passivation layer 111).

Also, in some embodiments, one or more additional layers (such as stress-reducing films) may be provided between the upper surface 120u of the semiconductor structure 120 and the encapsulation material 150. For example, a stress buffer layer or film (e.g., a silicone-based layer or film) may be selectively provided at one or more regions of the upper surface 120u (e.g., along portions of the edges 120e of the upper surface 120u that are free of the adhesion features 144, as shown in FIGS. 10B, 10D, and 10F). The stress buffer film may be configured to reduce or alleviate stress, for example, during thermal shock or other conditions that may induce thermomechanical stress in a power semiconductor device. More generally, such additional layers may be selectively provided between portions the upper surface 120u of the semiconductor structure 120 and the encapsulation material 150 so as to provide additional benefits (e.g., stress reduction and/or thermal resistance) while maintaining the enhanced adhesion between the encapsulation 150 and the semiconductor structure 120 provided by the adhesion features 144.

It will be understood that the arrangements of adhesion features 144 are illustrated by way of example only, and that embodiments of the present disclosure are not limited to these particular examples. More generally, embodiments of the present disclosure may include any arrangements and/or combinations of adhesion features 144 in repeating patterns in or on a semiconductor structure 120 that provide increased adhesion strength along the interface 151 between the semiconductor structure 120 and the encapsulation 150 thereon.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on,” “attached,” or extending “onto” another element, it can be directly on the other element or intervening elements may also be present. In contrast, when an element is referred to as being “directly on” or “directly attached” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Elements illustrated by dotted lines may be optional in the embodiments illustrated.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor structure comprising an active region;
an encapsulation material on the semiconductor structure; and
a plurality of adhesion features in or on the semiconductor structure along an interface with the encapsulation material, wherein the interface is laterally between the active region and at least one edge of the semiconductor structure.

2. The power semiconductor device of claim 1, wherein the adhesion features protrude from and/or are recessed in the semiconductor structure with a repeating pattern along the interface.

3. The power semiconductor device of claim 2, wherein the adhesion features are recessed in and comprise portions of the semiconductor structure.

4. The power semiconductor device of claim 2, wherein the adhesion features protrude from and comprise a material different than a semiconductor material of the semiconductor structure.

5. The power semiconductor device of claim 4, wherein a first adhesion strength between the adhesion features and the encapsulation material is greater than a second adhesion strength between the semiconductor structure and the encapsulation material.

6. The power semiconductor device of claim 5, wherein a third adhesion strength between the adhesion features and the semiconductor structure is greater than the second adhesion strength.

7. The power semiconductor device of claim 1, wherein the interface comprises an upper surface of the semiconductor structure that extends between the active region and the at least one edge, and a side surface of the semiconductor structure that extends from the at least one edge toward a bottom surface of the semiconductor structure.

8. The power semiconductor device of claim 1, wherein the adhesion features define rectangular, triangular, semi-elliptical, or trapezoidal shapes in cross-section.

9. The power semiconductor device of claim 1, wherein the adhesion features continuously extend along the interface in plan view.

10. The power semiconductor device of claim 1, wherein the adhesion features are distributed along the interface in plan view.

11. The power semiconductor device of claim 1, wherein an area density of the adhesion features at a corner portion of the semiconductor structure is greater than that of at least one other portion of the semiconductor structure along the interface.

12. The power semiconductor device of claim 11, wherein the at least one other portion of the semiconductor structure is free of the adhesion features along the interface.

13. The power semiconductor device of claim 1, further comprising:
a protective overcoating on the semiconductor structure laterally adjacent the encapsulation material and exposing the interface, wherein the protective overcoating comprises a non-conductive material different from that of the encapsulation material.

14. The power semiconductor device of claim 13, wherein the interface is a first interface, and wherein the plurality of adhesion features are further provided in or on the semiconductor structure along a second interface with the protective overcoating, wherein the second interface is laterally adjacent the first interface.

15. The power semiconductor device of claim 14, further comprising at least one insulating or conductive layer having the protective overcoating thereon, wherein the plurality of adhesion features are further provided in or on the semiconductor structure along a third interface with the at least one insulating or conductive layer.

16. The power semiconductor device of claim 13, wherein the power semiconductor device comprises a Schottky junction, and wherein the interface is laterally between an edge termination region of the Schottky junction and the at least one edge of the semiconductor structure.

17. The power semiconductor device of claim 13, wherein the power semiconductor device comprises a MOSFET.

18. The power semiconductor device of claim 1, wherein the semiconductor structure comprises a silicon carbide substrate and/or one or more silicon carbide epitaxial layers.

19. A power semiconductor device, comprising:
a semiconductor structure comprising an active region; and
a protective overcoating on the active region,
wherein a portion of the semiconductor structure that is laterally between at least one edge of the semiconductor structure and the protective overcoating comprises a patterned non-planar surface.

20. The power semiconductor device of claim 19, further comprising:
an encapsulation material directly on the patterned non-planar surface between the at least one edge of the semiconductor structure and the protective overcoating.

21. The power semiconductor device of claim 20, wherein the patterned non-planar surface comprises a plurality of adhesion features that protrude from and/or are recessed in the semiconductor structure with a repeating pattern along an interface with the encapsulation material.

22-29. (canceled)

30. A power semiconductor device, comprising:
a semiconductor structure;
a protective overcoating on an upper surface of the semiconductor structure; and
an encapsulation material on the semiconductor structure and the protective overcoating,
wherein, per unit length, a first interface with the encapsulation material that is laterally between at least one edge of the semiconductor structure and the protective overcoating has a greater surface area than a second interface with the encapsulation material that is vertically between the at least one edge and a bottom surface of the semiconductor structure.

31. The power semiconductor device of claim 30, wherein the semiconductor structure comprises a patterned non-planar surface along the first interface.

32. The power semiconductor device of claim 30, wherein the patterned non-planar surface comprises a plurality of adhesion features that protrude from and/or are recessed in the semiconductor structure with a repeating pattern along the first interface.

33-36. (canceled)

37. A method of fabricating a power semiconductor device, the method comprising:
providing a semiconductor structure comprising an active region;
forming a mask pattern on the semiconductor structure;
performing a patterning process using the mask pattern to form one or more device patterns on or adjacent the active region, and to form adhesion features in or on the semiconductor structure laterally between the active region and at least one edge of the semiconductor structure; and
forming an encapsulation material directly on the adhesion features.

38. The method of claim 37, wherein the adhesion features protrude from and/or are recessed in the semiconductor structure with a repeating pattern along an interface with the encapsulation material.

39. The method of claim 38, wherein, responsive to performing the patterning process, the adhesion features are recessed in and comprise portions of the semiconductor structure.

40. The method of claim 38, further comprising:
forming a material different than a semiconductor material of the semiconductor structure on the upper surface thereof prior to forming the mask pattern thereon,
wherein, responsive to performing the patterning process, the adhesion features protrude from and comprise the material different than the semiconductor material.

41-49. (canceled)
